(19) United States
(12) Patent Application Publication
(10) Pub. No.: US 2025/0046380 A1
(43) Pub. Date: Feb. 6, 2025

(54) SHALLOW ERASE FOR ERASE POOL MANAGEMENT

(71) Applicant: Western Digital Technologies, Inc., San Jose, CA (US)

(72) Inventors: Albert Bor Kai Chen, Milpitas, CA (US); Jiahui Yuan, Fremont, CA (US); Ken Oowada, Fujisawa (JP)

(73) Assignee: Western Digital Technologies, Inc., San Jose, CA (US)

(21) Appl. No.: 18/363,470

(22) Filed: Aug. 1, 2023

(51) Int. Cl. G11C 16/16; G11C 16/34

(52) U.S. Cl. CPC G11C 16/16; G11C 16/3445

(57) ABSTRACT

Technology is disclosed herein for a shallow erase for erase pool management. The memory system performs a shallow erase of a block of memory cells prior to placing the block in a shallow erase pool. The block may remain in the shallow erase pool for a substantial time with little to no risk of damage to the memory cells. The memory system completes the erase of the block at a later time. The memory system may select the block from the shallow erase pool when the system determines there is a need for another fully erased block. The erase voltage used for the shallow erase may be substantially lower in magnitude than the erase voltage used to complete the erase.

### BACKGROUND

The present disclosure relates to non-volatile memory.

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. Non-volatile memory allows information to be stored and retained even when the non-volatile memory is not connected to a source of power (e.g., a battery).

A memory structure in the memory system typically contains many memory cells and various control lines. The memory structure may be arranged into units that are referred to as blocks. For example, a block in a NAND memory system contains many NAND strings. A NAND string contains memory cell transistors connected in series, a drain side select gate at one end, and a source side select gate at the other end. Each select gate may have one or more transistors in series. Each NAND string is associated with a bit line. The block typically has many word lines that provide voltages to the control gates of the memory cell transistors. In some architectures, each word line connects to the control gate of one memory cell on each respective NAND string in the block.

The memory cells are programmed one group at a time. The unit of programming is typically referred to as a page. Typically, the memory cells are programmed to a number of data states. Using a greater number of data states allows for more bits to be stored per memory cell. For example, four data states may be used to store two bits per memory cell, eight data states may be used in order to store three bits per memory cell, 16 data states may be used to store four bits per memory cell, etc. Some memory cells may be programmed to a data state by storing charge in the memory cell. For example, the threshold voltage (Vt) of a NAND memory cell can be set to a target Vt by programming charge into a charge storage region such as a charge trapping layer. The amount of charge stored in the charge trapping layer establishes the Vt of the memory cell.

At some point in time the memory system may mark the programmed block for erase. The memory system may mark the block for erase responsive to, for example, a determination that the data in the block has been moved to a different block or is otherwise invalid. For memory such as NAND the block will be erased prior to programming new data in the block. For memory management, the memory system typically has a pool of blocks that can be used for programming. In one technique a block is erased prior to putting the block into the erase pool. If a block remains in the erased state for too long it may suffer damage. Therefore, some memory systems may place a limit on how long an erased block may remain in the erase pool.

In another technique, the block is placed into the erase pool without first being erased. Thus, when the memory system selects such a programmed block from the erase pool, the memory system will erase the block prior to programming. Erasing the programmed block just prior to programming may hurt device performance.

### BRIEF DESCRIPTION OF THE DRAWINGS

Like-numbered elements refer to common components in the different figures.

FIG. 1 is a block diagram depicting one embodiment of a storage system.

FIG. 2A is a block diagram of one embodiment of a memory die.

FIG. 2B is a block diagram of one embodiment of an integrated memory assembly.

FIGS. 3A and 3B depict different embodiments of integrated memory assemblies.

FIG. 4 is a perspective view of a portion of one example of a monolithic three dimensional memory structure.

FIG. 4A is a block diagram of one example of a memory structure having two planes.

FIG. 4B is a block diagram depicting a top view of a portion of physical block of memory cells.

FIG. 4C depicts an example of a stack showing a cross-sectional view along line AA of FIG. 4B.

FIG. 4D depicts a view of region 445 of FIG. 4C.

FIG. 4E is a schematic diagram of a portion of one example of a physical block, depicting several NAND strings.

FIG. 5A depicts a threshold voltage (Vt) distributions when each memory cells stores three bits.

FIG. 5B depicts a threshold voltage (Vt) distributions when each memory cells stores four bits.

FIG. 6A shows a simplified band diagram of a memory cell that has been erased fairly deeply such that it has a low Vt.

FIG. 6B shows a possible condition of the deeply erased memory cell at a later time at which there is charge pinning in the tunnel oxide, which has pulled positive charges (+) near the tunnel oxide.

FIG. 7A shows a simplified band diagram of a memory cell that has been left in the programmed state.

FIG. 7B shows a possible condition of the programmed memory cell at a later time at which there is charge pinning in the tunnel oxide (+), which has pulled negative charges (−) near the tunnel oxide.

FIG. 8 depicts a simplified band diagram of a memory cell that has undergone an embodiment of a shallow erase.

FIG. 9 shows another simplified band diagram for a programmed memory cell undergoing an erase that uses a high erase voltage.

FIG. 10 shows simplified band diagram for a programmed memory cell undergoing an embodiment of a shallow erase that uses a significantly lower erase voltage than the example in FIG. 9.

FIG. 11 is a flowchart of one embodiment of a process of shallow erase for erase pool management.

FIG. 12A shows example Vt distributions after one embodiment of a shallow erase in which the block was programmed to two bits per cell (four data states).

FIG. 12B depicts an example Vt distribution for the memory cells depicted in FIG. 12A after the final erase.

FIG. 13 is a flowchart of one embodiment of a process of a shallow erase.

FIG. 14 is a flowchart of one embodiment of a process of a final erase.

FIG. 15 is a flowchart of one embodiment of a process of a shallow erase.

FIG. 16 depicts a change in an erase Vt distribution during a conventional erase process.

FIG. 17 depicts a change in an erase Vt distribution during an embodiment of a shallow erase.

FIG. 18 depicts a change in an erase Vt distribution during an embodiment of a shallow erase.

FIG. 19 depicts a change in a programmed Vt distribution during a conventional erase process.

FIG. 20 depicts a change in a programmed Vt distribution during an embodiment of a shallow erase.

FIG. 21 depicts a change in a programmed Vt distribution during an embodiment of a shallow erase.

FIG. 22 is a flowchart describing one embodiment of a process for erasing memory cells for erase pool management.

### DETAILED DESCRIPTION

Technology is disclosed herein for a shallow erase for erase pool management. In an embodiment, when the memory system determines that a block of memory cells is to be returned to an erase pool, the memory system performs a shallow erase of the block prior to placing the block in a shallow erase pool. The block may remain in the shallow erase pool for a substantial time. The memory system may complete the erase of the block at a later time. The erase voltage used for the shallow erase may be substantially lower in magnitude than the erase voltage used to complete the erase. In an embodiment, the memory system will select the block from the shallow erase pool when the system determines there is or will soon be a need for another fully erased block. After the final erase, the threshold voltages (Vts) of the memory cells may be quite low. In some cases the Vts of the memory cells after the final erase may be negative. However, the average Vts of the memory cells after the shallow erase may be significantly greater. For example, the average Vts of the memory cells after the shallow erase may be non-negative. The shallow erased block may stay in the erase pool for a substantial time with little to no risk of damage to the memory cells. Therefore, damage that could occur by leaving fully erased blocks in an erase pool for a substantial time is avoided. Moreover, there is no need to remove the shallow erased block from the shallow erase pool after a short time (e.g., a few days) to prevent damage to the cells in the block. Therefore, erase pool management is simplified.

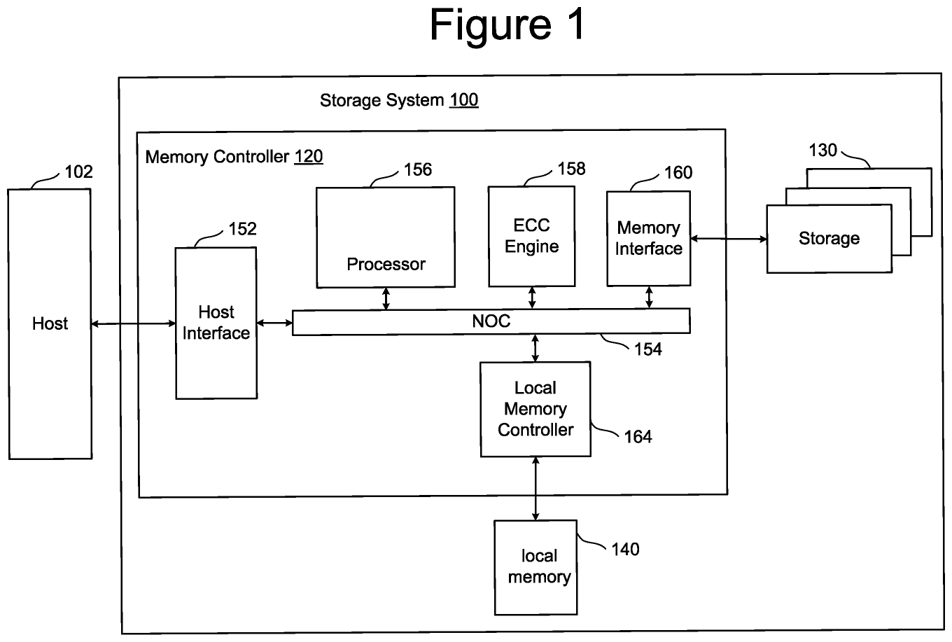

FIG. 1 is a block diagram of one embodiment of a storage system 100 that implements the technology described herein. The storage system 100 is configured to implement embodiments of shallow erase for erase pool block management. In one embodiment, storage system 100 is a solid state drive (“SSD”). Storage system 100 may be referred to as a “non-volatile storage system.” Storage system 100 can also be a memory card, USB drive or other type of storage system. The proposed technology is not limited to any one type of storage system. Storage system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 120 (or storage controller) connected to non-volatile storage 130 and local high speed memory 140 (e.g., DRAM, SRAM, MRAM). Local memory 140 is non-transitory memory, which may include volatile memory or non-volatile memory. Local high speed memory 140 is used by memory controller 120 to perform certain operations. For example, local high speed memory 140 may store logical to physical address translation tables (“L2P tables”).

Memory controller 120 comprises a host interface 152 that is connected to and in communication with host 102. In one embodiment, host interface 152 implements an NVM Express (NVMe) over PCI Express (PCIe). Other interfaces can also be used, such as SCSI, SATA, etc. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus. Connected to and in communication with NOC 154 is processor 156, ECC engine 158, memory interface 160, and local memory controller 164. Local memory controller 164 is used to operate and communicate with local high speed memory 140 (e.g., DRAM, SRAM, MRAM).

ECC engine 158 performs error correction services. For example, ECC engine 158 performs data encoding and decoding. In one embodiment, ECC engine 158 is an electrical circuit programmed by software. For example, ECC engine 158 can be a processor that can be programmed. In other embodiments, ECC engine 158 is a custom and dedicated hardware circuit without any software. In another embodiment, the function of ECC engine 158 is implemented by processor 156.

Processor 156 performs the various controller memory operations, such as programming, erasing, reading, and memory management processes. In an embodiment, processor 156 performs erase pool management. The processor 156 may instruct the storage 130 to perform a shallow erase of a block of memory cells. After the shallow erase the block may be placed into a shallow erase pool, which may be a list of blocks that have undergone shallow erase. A copy of the list of blocks in the shallow erase pool may be at least temporarily stored in local memory 140. In some embodiment, a copy of the list of blocks in the shallow erase pool may be stored in the storage 130 to provide for non-volatile storage. In one embodiment after the system 100 completes the erase of the shallow erased block, the block is transferred from the shallow erase pool to a complete erased pool, which is a list of blocks that have completed erase and are thus ready for programming. In one embodiment, processor 156 is programmed by firmware. In other embodiments, processor 156 is a custom and dedicated hardware circuit without any software.

Processor 156 also implements a translation module, as a software/firmware process or as a dedicated hardware circuit. In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory dies. To implement this system, memory controller 120 (e.g., the translation module) performs address translation between the logical addresses used by the host and the physical addresses used by the memory die. One example implementation is to maintain tables (i.e. the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 140 cannot hold all of the L2P tables. In such a case, the entire set of L2P tables are stored in a storage 130 and a subset of the L2P tables are cached (L2P cache) in the local high speed memory 140.

Memory interface 160 communicates with non-volatile storage 130. In one embodiment, memory interface provides a Toggle Mode interface. Other interfaces can also be used. In some example implementations, memory interface 160 (or another portion of controller 120) implements a scheduler and buffer for transmitting data to and receiving data from one or more memory die.

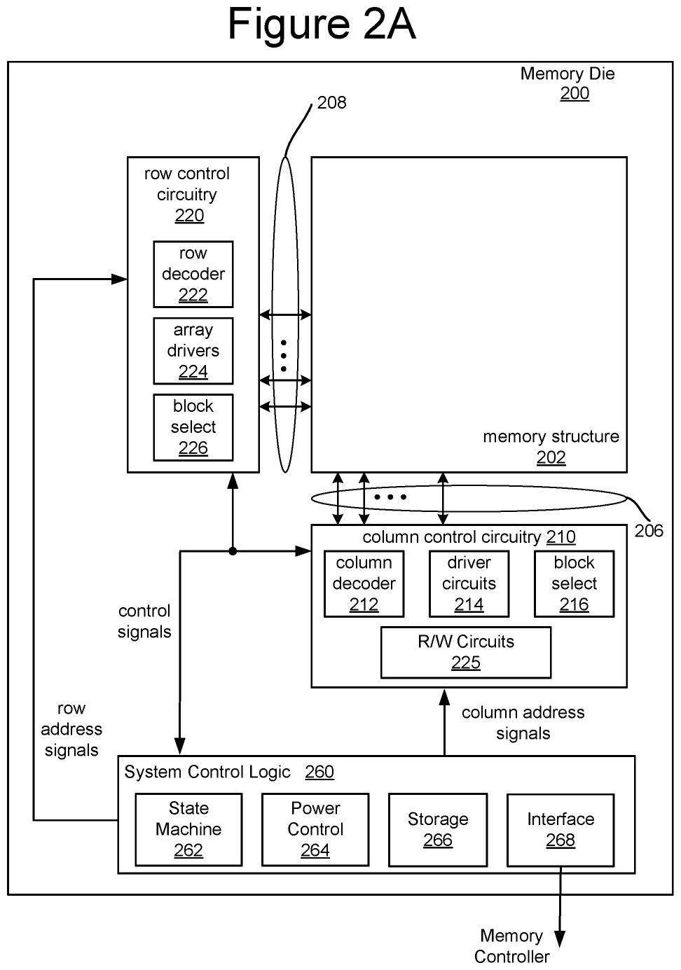

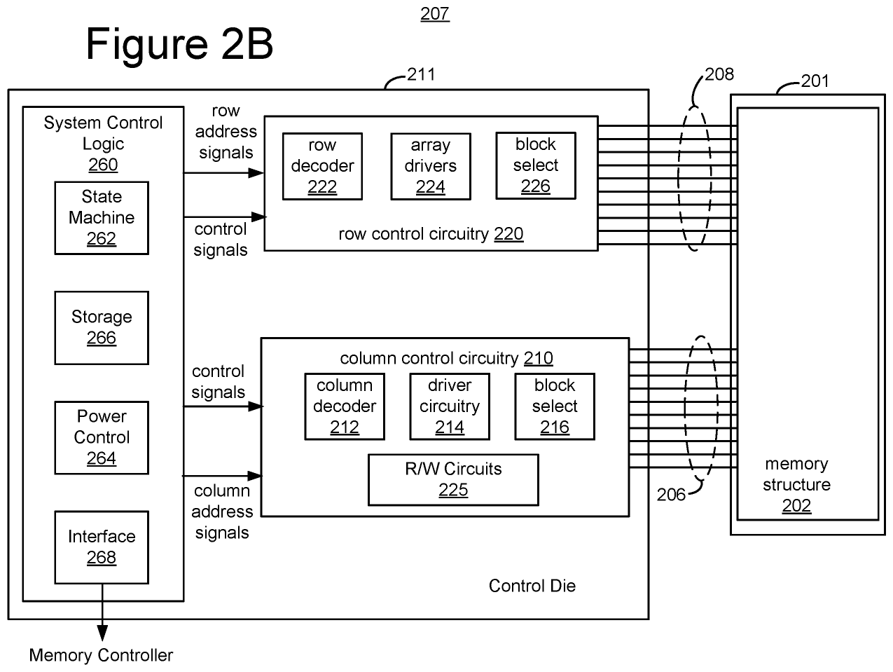

In one embodiment, non-volatile storage 130 comprises one or more memory dies. FIG. 2A is a functional block diagram of one embodiment of a memory die 200 that comprises non-volatile storage 130. Each of the one or more memory dies of non-volatile storage 130 can be implemented as memory die 200 of FIG. 2A. The components depicted in FIG. 2B are electrical circuits. Memory die 200 includes a memory structure 202 (e.g., memory array) that can comprise non-volatile memory cells (also referred to as non-volatile storage cells), as described in more detail below. The array terminal lines of memory structure 202 include the various layer(s) of word lines organized as rows, and the various layer(s) of bit lines organized as columns. However, other orientations can also be implemented. Memory die 200 includes row control circuitry 220, whose outputs are connected to respective word lines of the memory structure 202. Row control circuitry 220 receives a group of M row address signals and one or more various control signals from System Control Logic circuit 260, and typically may include such circuits as row decoders 222, array drivers 224, and block select circuitry 226 for both reading and writing (programming) operations. Row control circuitry 220 may also include read/write circuitry. Memory die 200 also includes column control circuitry 210 including read/write circuits 225. The read/write circuits 225 may contain sense amplifiers and data latches. The sense amplifier(s) input/outputs are connected to respective bit lines of the memory structure 202. Although only a single block is shown for structure 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, block select 216, as well as read/write circuitry 225, and I/O multiplexers.

System control logic 260 receives data and commands from memory controller 120 and provides output data and status to the host. In some embodiments, the system control logic 260 (which comprises one or more electrical circuits) includes state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 260 can also include a power control module 264 that controls the power and voltages supplied to the rows and columns of the memory structure 202 during memory operations. System control logic 260 includes storage 266 (e.g., RAM, registers, latches, etc.), which may be used to store parameters for operating the memory structure 202.

Commands and data are transferred between memory controller 120 and memory die 200 via memory controller interface 268 (also referred to as a “communication interface”). Memory controller interface 268 is an electrical interface for communicating with memory controller 120. Examples of memory controller interface 268 include a Toggle Mode Interface and an Open NAND Flash Interface (ONFI). Other I/O interfaces can also be used. In one embodiment, the memory die 200 receives a command via memory controller interface 268 to perform a post-program erase.

In some embodiments, all the elements of memory die 200, including the system control logic 260, can be formed as part of a single die. In other embodiments, some or all of the system control logic 260 can be formed on a different die than the die that contains the memory structure 202.

In one embodiment, memory structure 202 comprises a three-dimensional memory array of non-volatile memory cells in which multiple memory levels are formed above a single substrate, such as a wafer. The memory structure may comprise any type of non-volatile memory that are monolithically formed in one or more physical levels of memory cells having an active area disposed above a silicon (or other type of) substrate. In one example, the non-volatile memory cells comprise vertical NAND strings with charge-trapping layers.

In another embodiment, memory structure 202 comprises a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or other wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) memory structure 202 and (2) peripheral circuitry, which includes all of the other components depicted in FIG. 2B. An important characteristic of a memory circuit is its capacity, which can be increased by increasing the area of the memory die of storage system 100 that is given over to the memory structure 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die for the storage system 100 is the amount of area to devote to the memory structure 202 and the amount of area to devote to the peripheral circuitry.

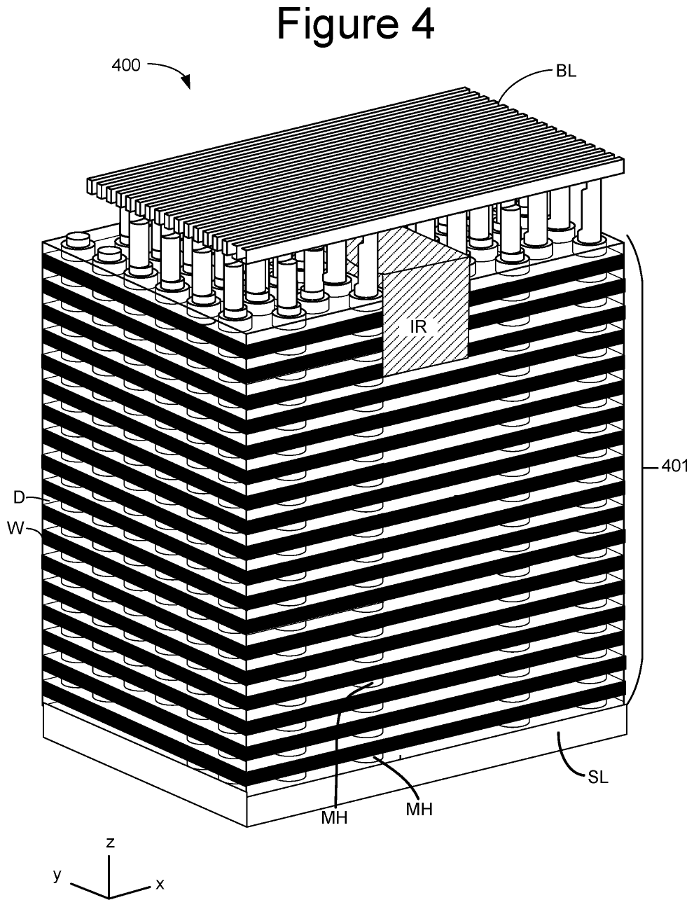

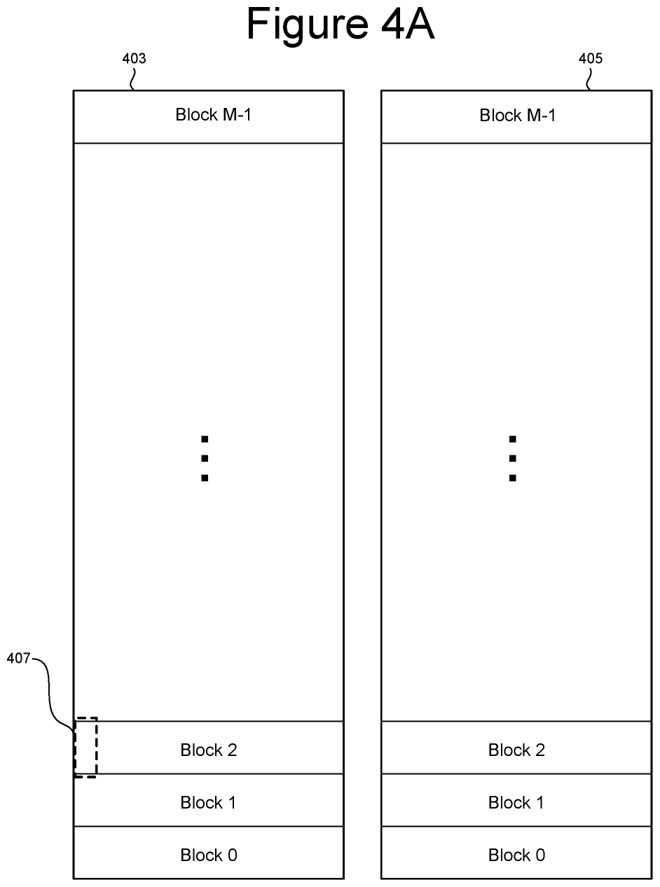

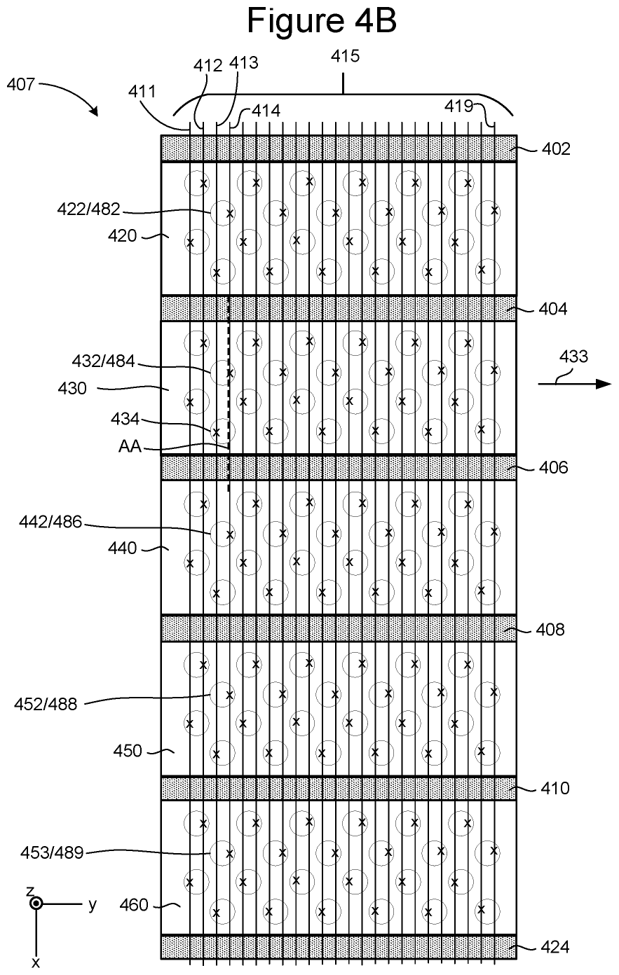

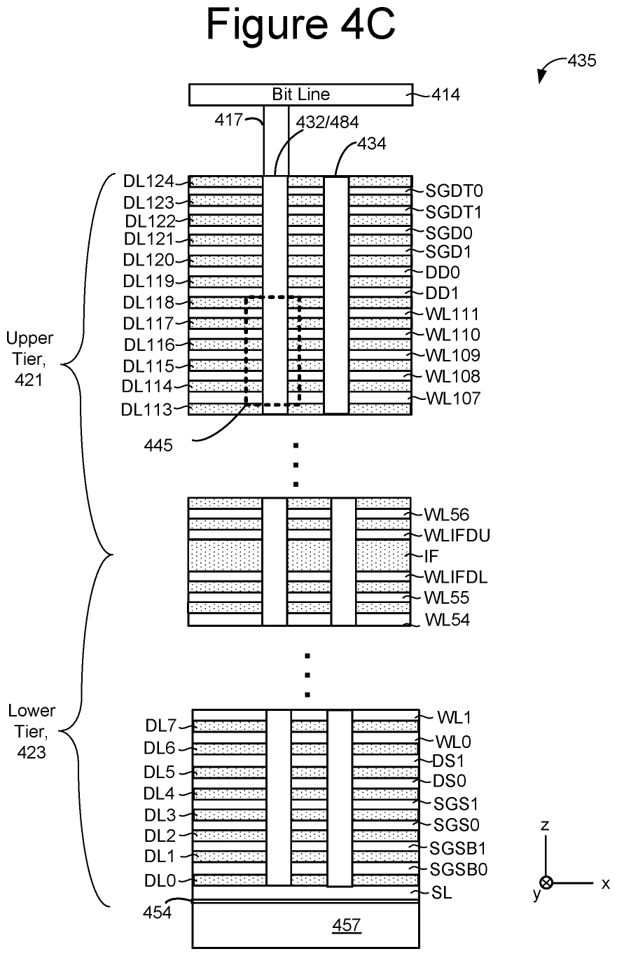

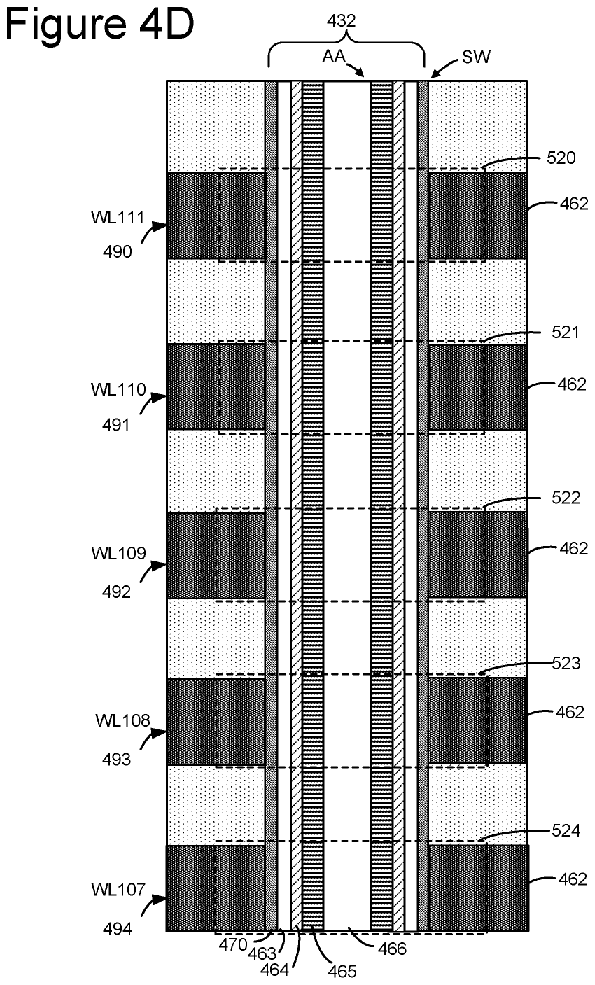

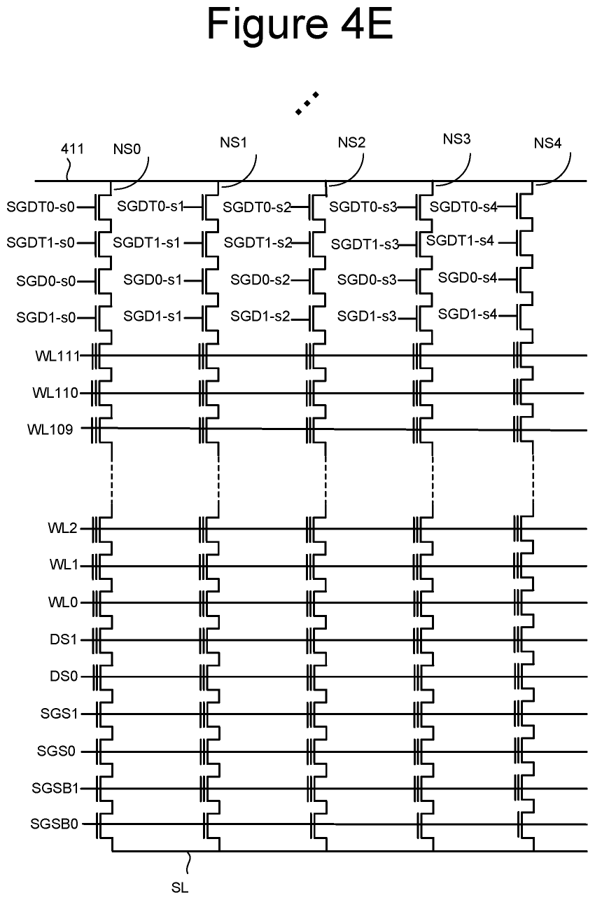

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ PMOS devices. Processing operations for manufacturing a CMOS die will differ in many aspects from the processing operations optimized for an NMOS flash NAND memory or other memory cell technologies. Three-dimensional NAND structures (see, for example, FIG. 4) in particular may benefit from specialized processing operations.

To improve upon these limitations, embodiments described below can separate the elements of FIG. 2A onto separately formed dies that are then bonded together. More specifically, the memory structure 202 can be formed on one die (referred to as the memory die) and some or all of the peripheral circuitry elements, including one or more control circuits, can be formed on a separate die (referred to as the control die). For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology. For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on one die connected to the periphery elements on the other die. Although the following will focus on a bonded memory circuit of one memory die and one control die, other embodiments can use more dies, such as two memory dies and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 207. One or more integrated memory assemblies 207 may be used to implement the non-volatile storage 130 of storage system 100. The integrated memory assembly 207 includes two types of semiconductor dies (or more succinctly, “die”). Memory structure die 201 includes memory structure 202. Memory structure 202 includes non-volatile memory cells. Control die 211 includes control circuitry 260, 210, and 220 (as described above). In some embodiments, control die 211 is configured to connect to the memory structure 202 in the memory structure die 201. In some embodiments, the memory structure die 201 and the control die 211 are bonded together.

FIG. 2B shows an example of the peripheral circuitry, including control circuits, formed in a peripheral circuit or control die 211 coupled to memory structure 202 formed in memory structure die 201. Common components are labelled similarly to FIG. 2A. System control logic 260, row control circuitry 220, and column control circuitry 210 are located in control die 211. In some embodiments, all or a portion of the column control circuitry 210 and all or a portion of the row control circuitry 220 are located on the memory structure die 201. In some embodiments, some of the circuitry in the system control logic 260 is located on the on the memory structure die 201.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate controller 120 may also be used to fabricate system control logic 260, row control circuitry 220, and column control circuitry 210). Thus, while moving such circuits from a die such as memory structure die 201 may reduce the number of steps needed to fabricate such a die, adding such circuits to a die such as control die 211 may not require many additional process steps. The control die 211 could also be referred to as a CMOS die, due to the use of CMOS technology to implement some or all of control circuitry 260, 210, 220.

FIG. 2B shows column control circuitry 210 including read/write circuits 225 on the control die 211 coupled to memory structure 202 on the memory structure die 201 through electrical paths 206. For example, electrical paths 206 may provide electrical connection between column decoder 212, driver circuitry 214, and R/W circuits 225 and bit lines of memory structure 202. Electrical paths may extend from column control circuitry 210 in control die 211 through pads on control die 211 that are bonded to corresponding pads of the memory structure die 201, which are connected to bit lines of memory structure 202. Each bit line of memory structure 202 may have a corresponding electrical path in electrical paths 206, including a pair of bond pads, which connects to column control circuitry 210. Similarly, row control circuitry 220, including row decoder 222, array drivers 224, and block select 226 are coupled to memory structure 202 through electrical paths 208. Each electrical path 208 may correspond to a word line, dummy word line, or select gate line. Additional electrical paths may also be provided between control die 211 and memory structure die 201.

For purposes of this document, the phrases “a control circuit” or “one or more control circuits” can include, but is not limited to, any one of or any combination of state memory controller 120, processor 156, state machine 262, power control 264, all or a portion of system control logic 260, all or a portion of row control circuitry 220, all or a portion of column control circuitry 210, read/write circuits 225, sense amps, a microcontroller, a microprocessor, and/or other similar functioned circuits. A control circuit can include hardware only or a combination of hardware and software (including firmware). For example, a controller programmed by firmware to perform the functions described herein is one example of a control circuit. A control circuit can include a processor, FPGA, ASIC, integrated circuit, or other type of circuit.

For purposes of this document, the term “apparatus” can include, but is not limited to, one or more of, storage system 100, storage 130, memory die 200, integrated memory assembly 207, and/or control die 211.

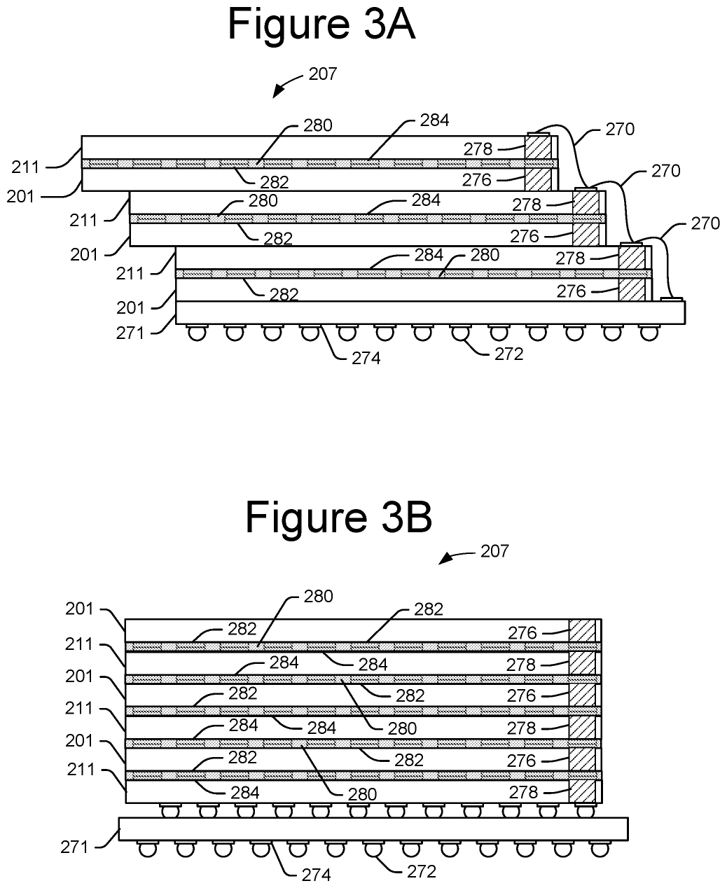

In some embodiments, there is more than one control die 211 and more than one memory structure die 201 in an integrated memory assembly 207. In some embodiments, the integrated memory assembly 207 includes a stack of multiple control dies 211 and multiple memory structure dies 201. FIG. 3A depicts a side view of an embodiment of an integrated memory assembly 207 stacked on a substrate 271 (e.g., a stack comprising control die 211 and memory structure die). The integrated memory assembly 207 has three control dies 211 and three memory structure dies 201. In some embodiments, there are more than three memory structure dies 201 and more than three control dies 211. In FIG. 3A there are an equal number of memory structure dies 201 and control dies 211; however, in one embodiment, there are more memory structure dies 201 than control dies 211. For example, one control die 211 could control multiple memory structure dies 201.

Each control die 211 is affixed (e.g., bonded) to at least one of the memory structure die 201. Some of the bond pads 282/284 are depicted. There may be many more bond pads. A space between two die 201, 211 that are bonded together is filled with a solid layer 280, which may be formed from epoxy or other resin or polymer. This solid layer 280 protects the electrical connections between the die 201, 211, and further secures the die together. Various materials may be used as solid layer 280.

The integrated memory assembly 207 may for example be stacked with a stepped offset, leaving the bond pads at each level uncovered and accessible from above. Wire bonds 270 connected to the bond pads connect the control die 211 to the substrate 271. A number of such wire bonds may be formed across the width of each control die 211 (i.e., into the page of FIG. 3A).

A memory die through silicon via (TSV) 276 may be used to route signals through a memory structure die 201. A control die through silicon via (TSV) 278 may be used to route signals through a control die 211. The TSVs 276, 278 may be formed before, during or after formation of the integrated circuits in the semiconductor dies 201, 211. The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, doped polysilicon, and alloys or combinations thereof may be used.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package. The solder balls 272 may form a part of the interface between integrated memory assembly 207 and memory controller 120.

FIG. 3B depicts a side view of another embodiment of an integrated memory assembly 207 stacked on a substrate 271. The integrated memory assembly 207 of FIG. 3B has three control dies 211 and three memory structure dies 201. In some embodiments, there are many more than three memory structure dies 201 and many more than three control dies 211. In this example, each control die 211 is bonded to at least one memory structure die 201. Optionally, a control die 211 may be bonded to two or more memory structure dies 201.

Some of the bond pads 282, 284 are depicted. There may be many more bond pads. A space between two dies 201, 211 that are bonded together is filled with a solid layer 280, which may be formed from epoxy or other resin or polymer. In contrast to the example in FIG. 3A, the integrated memory assembly 207 in FIG. 3B does not have a stepped offset. A memory die through silicon via (TSV) 276 may be used to route signals through a memory structure die 201. A control die through silicon via (TSV) 278 may be used to route signals through a control die 211.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package.

As has been briefly discussed above, the control die 211 and the memory structure die 201 may be bonded together. Bond pads on each die 201, 211 may be used to bond the two die together. In some embodiments, the bond pads are bonded directly to each other, without solder or other added material, in a so-called Cu-to-Cu bonding process. In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension. Such bonds may be formed at room temperature, though heat may also be applied. In embodiments using Cu-to-Cu bonding, the bond pads may be about 5 μm square and spaced from each other with a pitch of 5 μm to 5 μm. While this process is referred to herein as Cu-to-Cu bonding, this term may also apply even where the bond pads are formed of materials other than Cu.

When the area of bond pads is small, it may be difficult to bond the semiconductor dies together. The size of, and pitch between, bond pads may be further reduced by providing a film layer on the surfaces of the semiconductor die including the bond pads. The film layer is provided around the bond pads. When the die are brought together, the bond pads may bond to each other, and the film layers on the respective die may bond to each other. Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller sizes and pitches.

Some embodiments may include a film on surface of the dies 201, 211. Where no such film is initially provided, a space between the die may be under filled with an epoxy or other resin or polymer. The under-fill material may be applied as a liquid which then hardens into a solid layer. This under-fill step protects the electrical connections between the dies 201, 211, and further secures the die together. Various materials may be used as under-fill material.

FIG. 4 is a perspective view of a portion of one example of a monolithic three dimensional memory array/structure that can comprise memory structure 202, which includes a plurality non-volatile memory cells arranged as vertical NAND strings. For example, FIG. 4 shows a portion 400 of one block of memory. The structure depicted includes a set of bit lines BL positioned above a stack 401 of alternating dielectric layers and conductive layers. For example purposes, one of the dielectric layers is marked as D and one of the conductive layers (also called word line layers) is marked as W. The number of alternating dielectric layers and conductive layers can vary based on specific implementation requirements. In one embodiment the alternating dielectric layers and conductive layers are divided into four (or a different number of) regions (e.g., sub-blocks) by isolation regions IR. FIG. 4 shows one isolation region IR separating two sub-blocks. Below the alternating dielectric layers and word line layers is a source line layer SL. Memory holes are formed in the stack of alternating dielectric layers and conductive layers. For example, one of the memory holes is marked as MH. Note that in FIG. 4, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data. More details of the three dimensional monolithic memory array that comprises memory structure 202 is provided below.

FIG. 4A is a block diagram explaining one example organization of memory structure 202, which is divided into two planes 403 and 405. Each plane is then divided into M blocks. In one example, each plane has about 2000 blocks. However, different numbers of blocks and planes can also be used. In one embodiment, a block of memory cells is a unit of erase. That is, all memory cells of a block are erased together. In other embodiments, blocks can be divided into sub-blocks and the sub-blocks can be the unit of erase. Memory cells can also be grouped into blocks for other reasons, such as to organize the memory structure to enable the signaling and selection circuits. In some embodiments, a block represents a group of connected memory cells as the memory cells of a block share a common set of word lines. For example, the word lines for a block are all connected to all of the vertical NAND strings for that physical block. Although FIG. 4A shows two planes 403/405, more or fewer than two planes can be implemented. In some embodiments, memory structure 202 includes four planes. In some embodiments, memory structure 202 includes eight planes. In some embodiments, programming can be performed in parallel in a first selected block in plane 403 and a second selected block in plane 405.

FIGS. 4B-4E depict an example three dimensional (“3D”) NAND structure that corresponds to the structure of FIG. 4 and can be used to implement memory structure 202 of FIGS. 2B and 2C. FIG. 4B is a diagram depicting a top view of a portion 407 of Block 2. As can be seen from FIG. 4B, the block depicted in FIG. 4B extends in the direction of arrow 433. In one embodiment, the memory array has many layers; however, FIG. 4B only shows the top layer.

FIG. 4B depicts a plurality of circles that represent the vertical columns. Each of the vertical columns include multiple select transistors (also referred to as a select gate or selection gate) and multiple memory cells. In one embodiment, each vertical column implements a NAND string. For example, FIG. 4B depicts vertical columns 422, 432, 442, 452 and 453. Vertical column 422 implements NAND string 482. Vertical column 432 implements NAND string 484. Vertical column 442 implements NAND string 486. Vertical column 452 implements NAND string 488. Vertical column 453 implements NAND string 486. Vertical column 452 implements NAND string 489. More details of the vertical columns are provided below. Since the physical block depicted in FIG. 4B extends in the direction of arrow 433, the physical block includes more vertical columns than depicted in FIG. 4B.

FIG. 4B also depicts a set of bit lines 415, including bit lines 411, 412, 413, 414, . . . 419. FIG. 4B shows 24 bit lines because only a portion of the block is depicted. It is contemplated that more than 24 bit lines connected to vertical columns of the block. Each of the circles representing vertical columns has an “x” to indicate its connection to one bit line. For example, bit line 414 is connected to vertical columns 422, 432, 442, 452, and 453.

The block depicted in FIG. 4B includes a set of isolation regions 402, 404, 406, 408, 410, and 424, which may be formed of SiO₂; however, other dielectric materials can also be used. Isolation regions 402, 404, 406, 408, 410, and 424 serve to divide the top layers of the physical block into five regions; for example, the top layer depicted in FIG. 4B is divided into regions 420, 430, 440, 450, and 460 of which are referred to as sub-blocks. In one embodiment, isolation regions 402 and 424 separate the block from adjacent blocks. Thus, isolation regions 402 and 424 may extend down to the substrate. In one embodiment, the isolation regions 404, 406, 408, and 410 only divide the layers used to implement select gates so that NAND strings in different sub-blocks can be independently selected. Referring back to FIG. 4, the IR region may correspond to any of isolation regions 404, 406, 408, or 410.

In one example implementation, a bit line only connects to one vertical column/NAND string in each of regions (sub-blocks) 420, 430, 440, 450, and 460. In that implementation, each block has twenty rows of active columns and each bit line connects to five rows in each block. In one embodiment, all of the five vertical columns/NAND strings connected to a common bit line are connected to the same word line (or set of word lines); therefore, the system uses the drain side selection lines to choose one (or another subset) of the five to be subjected to a memory operation (program, verify, read, and/or erase).

Although FIG. 4B shows each region (420, 430, 440, 450, 460) having four rows of vertical columns, five regions (420, 430, 440, 450, 460) and twenty rows of vertical columns in a block, those exact numbers are an example implementation. Other embodiments may include more or fewer regions (420, 430, 440, 450, 460) per block, more or fewer rows of vertical columns per region and more or fewer rows of vertical columns per block. FIG. 4B also shows the vertical columns being staggered. In other embodiments, different patterns of staggering can be used. In some embodiments, the vertical columns are not staggered.

FIG. 4C depicts an example of a stack 435 showing a cross-sectional view along line AA of FIG. 4B. The SGD layers include SGDT0, SGDT1, SGD0, and SGD1. The SGD layers may have more or fewer than four layers. The SGS layers includes SGSB0, SGSB1. SGS0, and SGS1. The SGS layers may have more or fewer than four layers. Four dummy word line layers DD0, DD1, DS1, and DS0 are provided, in addition to the data word line layers WL0-WL111. There may be more or fewer than 112 data word line layers and more or fewer than four dummy word line layers. Each NAND string has a drain side select gate at the SGD layers. Each NAND string has a source side select gate at the SGS layers. Also depicted are dielectric layers DL0-DL124.

Columns 432, 434 of memory cells are depicted in the multi-layer stack. The stack includes a substrate 457, an insulating film 454 on the substrate, and a portion of a source line SL. A portion of the bit line 414 is also depicted. Note that NAND string 484 is connected to the bit line 414. NAND string 484 has a source-end at a bottom of the stack and a drain-end at a top of the stack. The source-end is connected to the source line SL. A conductive via 417 connects the drain-end of NAND string 484 to the bit line 414.

In one embodiment, the memory cells are arranged in NAND strings. The word line layers WL0-WL111 connect to memory cells (also called data memory cells). Dummy word line layers DD0, DD1, DS0 and DS1 connect to dummy memory cells. A dummy memory cell does not store and is not eligible to store host data (data provided from the host, such as data from a user of the host), while a data memory cell is eligible to store host data. In some embodiments, data memory cells and dummy memory cells may have a same structure. Drain side select layers SGD are used to electrically connect and disconnect (or cut off) the channels of respective NAND strings from bit lines. Source side select layers SGS are used to electrically connect and disconnect (or cut off) the channels of respective NAND strings from the source line SL.

FIG. 4D depicts a view of the region 445 of FIG. 4C. Data memory cell transistors 520, 521, 522, 523, and 524 are indicated by the dashed lines. A number of layers can be deposited along the sidewall (SW) of the memory hole 432 and/or within each word line layer, e.g., using atomic layer deposition. For example, each column (e.g., the pillar which is formed by the materials within a memory hole) can include a blocking oxide/block high-k material 470, charge-trapping layer or film 463 such as SiN or other nitride, a tunneling layer 464, a polysilicon body or channel 465, and a dielectric core 466. A word line layer can include a conductive metal 462 such as Tungsten as a control gate. For example, control gates 490, 491, 492, 493 and 494 are provided. In this example, all of the layers except the metal are provided in the memory hole. In other approaches, some of the layers can be in the control gate layer. Additional pillars are similarly formed in the different memory holes. A pillar can form a columnar active area (AA) of a NAND string.

When a data memory cell transistor is programmed, electrons are stored in a portion of the charge-trapping layer which is associated with the data memory cell transistor. These electrons are drawn into the charge-trapping layer from the channel, and through the tunneling layer. The Vth of a data memory cell transistor is increased in proportion to the amount of stored charge. During an erase operation, the electrons return to the channel.

Each of the memory holes can be filled with a plurality of annular layers (also referred to as memory film layers) comprising a blocking oxide layer, a charge trapping layer, a tunneling layer and a channel layer. A core region of each of the memory holes is filled with a body material, and the plurality of annular layers are between the core region and the WLLs in each of the memory holes. In some cases, the tunneling layer 464 can comprise multiple layers such as in an oxide-nitride-oxide configuration.

FIG. 4E is a schematic diagram of a portion of the memory array 202. FIG. 4E shows physical data word lines WL0-WL111 running across the entire block. The structure of FIG. 4E corresponds to a portion 407 in Block 2 of FIG. 4A, including bit line 411. Within the physical block, in one embodiment, each bit line is connected to five NAND strings. Thus, FIG. 4E shows bit line 411 connected to NAND string NS0, NAND string NS1, NAND string NS2, NAND string NS3, and NAND string NS4.

In one embodiment, there are five sets of drain side select lines in the block. For example, the set of drain side select lines connected to NS0 include SGDT0-s0, SGDT1-s0, SGD0-s0, and SGD1-s0. The set of drain side select lines connected to NS1 include SGDT0-s1, SGDT1-s1, SGD0-s1, and SGD1-s1. The set of drain side select lines connected to NS2 include SGDT0-s2, SGDT1-s2, SGD0-s2, and SGD1-s2. The set of drain side select lines connected to NS3 include SGDT0-s3, SGDT1-s3, SGD0-s3, and SGD1-s3. The set of drain side select lines connected to NS4 include SGDT0-s4, SGDT1-s4, SGD0-s4, and SGD1-s4. Herein the term “SGD” may be used as a general term to refer to any one or more of the lines in a set of drain side select lines. In an embodiment, each line in a given set may be operated independent from the other lines in that set to allow for different voltages to the gates of the four drain side select transistors on the NAND string. Moreover, each set of drain side select lines can be selected independent of the other sets. Each set drain side select lines connects to a group of NAND strings in the block. Only one NAND string of each group is depicted in FIG. 4E. These five sets of drain side select lines correspond to five sub-blocks. A first sub-block corresponds to those vertical NAND strings controlled by SGDT0-s0, SGDT1-s0, SGD0-s0, and SGD1-s0. A second sub-block corresponds to those vertical NAND strings controlled by SGDT0-s1, SGDT1-s1, SGD0-s1, and SGD1-s1. A third sub-block corresponds to those vertical NAND strings controlled by SGDT0-s2, SGDT1-s2, SGD0-s2, and SGD1-s2. A fourth sub-block corresponds to those vertical NAND strings controlled by SGDT0-s3, SGDT1-s3, SGD0-s3, and SGD1-s3. A fifth sub-block corresponds to those vertical NAND strings controlled by SGDT0-s4, SGDT1-s4, SGD0-s4, and SGD1-s4. As noted, FIG. 4E only shows the NAND strings connected to bit line 411. However, a full schematic of the block would show every bit line and five vertical NAND strings connected to each bit line.

In one embodiment, all of the memory cells on the NAND strings in a physical block are erased as a unit. However in some embodiments, a block is operated as an upper tier 421 and a lower tier 423, wherein the upper tier and the lower tier each form an erase unit. For example, memory cells connected to WL0-WL61 may be in the lower tier and memory cells connected to WL62-WL111 may be in the upper tier. Hence, memory cells connected to WL0-WL61 may be in one erase unit and memory cells connected to WL62-WL111 may be in another erase unit. A block could be operated in more than two tiers. Erase units can be formed based on other divisions of blocks.

Although the example memories of FIGS. 4-4E are three dimensional memory structure that includes vertical NAND strings with charge-trapping material, other 3D memory structures can also be used with the technology described herein.

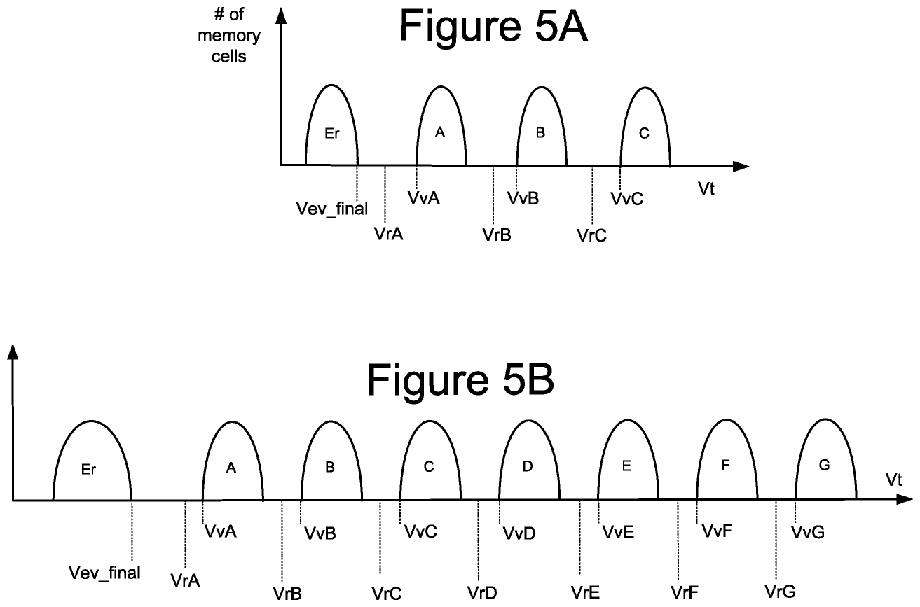

The storage systems discussed above can be erased, programmed and read. At the end of a successful programming process, the Vts of the memory cells should be within one or more distributions of Vts for programmed memory cells or within a distribution of Vts for erased memory cells, as appropriate. Memory cells that store one bit of data per memory cell data are referred to as single level cells (“SLC”). The data stored in SLC memory cells is referred to as SLC data; therefore, SLC data comprises one bit per memory cell. Memory cells that store multiple bit per memory cell data are referred to as multi-level cells (“MLC”). The data stored in MLC memory cells is referred to as MLC data; therefore, MLC data comprises multiple bits per memory cell. Data stored as multiple bits of data per memory cell is MLC data. In the example embodiment of FIG. 5A, each memory cell stores two bits of data. Other embodiments may use other data capacities per memory cell. The first Vt distribution (data state) Er represents memory cells that are erased. The other three Vt distributions (data states) A-C represent memory cells that are programmed and, therefore, are also called programmed states. Three program verify levels (VvA, VvB, and VvC) are depicted. Three read levels (VrA, VrB, and VrC) are depicted. A final erase verify level (VeV_final) is depicted. The final erase verify level is used for a final erase of the memory cells to complete the erase. Optionally, there may be a shallow erase verify level to be used for verify during a shallow erase. However, it is not required that the shallow erase have a verify operation.

FIG. 5B shows eight Vt distributions, corresponding to eight data states. The first Vt distribution (data state) Er represents memory cells that are erased. The other seven Vt distributions (data states) A-G represent memory cells that are programmed and, therefore, are also called programmed states. Each Vt distribution (data state) corresponds to predetermined values for the set of data bits. The specific relationship between the data programmed into the memory cell and the Vt levels of the cell depends upon the data encoding scheme adopted for the cells. In one embodiment, data values are assigned to the Vt ranges using a Gray code assignment so that if the Vt of a memory erroneously shifts to its neighboring physical state, only one bit will be affected. In an embodiment, the number of memory cells in each state is about the same.

FIG. 5B shows seven read reference voltages, VrA, VrB, VIC, VrD, VrE, VrF, and VrG for reading data from memory cells. By testing (e.g., performing sense operations) whether the Vt of a given memory cell is above or below the seven read reference voltages, the system can determine what data state (i.e., A, B, C, D, . . . ) a memory cell is in. FIG. 5A also shows a number of verify reference voltages. The verify reference voltages are VvA. VvB. VvC. VVD, VvE, VvF, and VvG. In some embodiments, when programming memory cells to data state A, the system will test whether those memory cells have a Vt greater than or equal to VvA. If the memory cell has a Vt greater than or equal to VvA, then the memory cell is locked out from further programming. Similar reasoning applies to the other data states. A final erase verify level (VeV_final) is depicted. The final erase verify level is used for a final erase of the memory cells to complete the erase. Optionally, there may be a shallow erase verify level to be used for verify during a shallow erase. However, it is not required that the shallow erase have a verify operation.

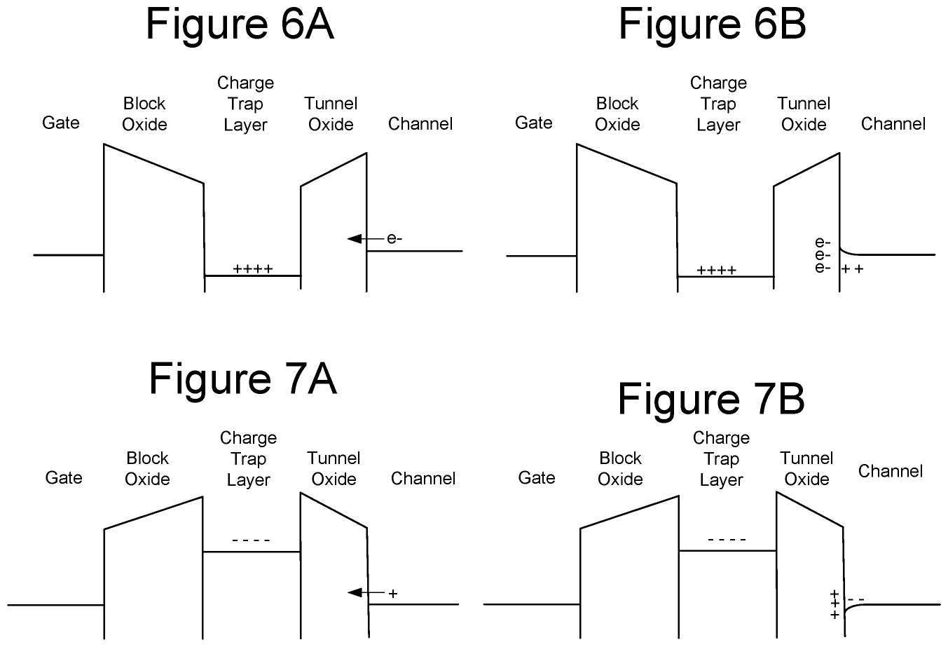

A conventional technique of fully erasing memory cells prior to placing the block into an erase pool can create problems. One problem pertains to charge pinning. FIG. 6A shows an example simplified band diagram of a memory cell that has been erased fairly deeply such that it has a low Vt. The Vt may be negative. Erasing a NAND memory cell removes negative charges from the charge trap layer. Moreover, a deep erase can leave positive charges in the charge trap layer, as indicated in FIG. 6A. The charge pinning is represented by the electron (e−) being drawn from the channel to the tunnel oxide. FIG. 6B shows a possible condition of the deeply erased memory cell at a later time at which there is charge pinning in the tunnel oxide, which has pulled positive charges (+) near the tunnel oxide. Such charge pinning can potentially lead to damage of the tunnel oxide. Some conventional techniques may avoid leaving such a deeply erased block in the erase pool for an extended amount of time. For example, the memory system could limit the time a deeply erased block can stay in the erase pool to a few days. However, this complicates erase pool management.

One possible technique is to leave the block in the programmed state when the block is placed into the erase pool and only erase the block after it is removed from the erase pool for programming. FIG. 7A shows an example simplified band diagram of a memory cell that has been left in the programmed state. The Vt of a given memory cell may be quite high, which is indicated by the negative charges (−) in the charge trap layer. Programming a NAND memory cell may add negative charges to the charge trap layer. However, this can also result in charge pinning, which is represented by the positive charge (+) being drawn from the channel to the tunnel oxide. FIG. 7B shows a possible condition of the programmed memory cell at a later time at which there is charge pinning in the tunnel oxide (+), which has pulled negative charges (−) near the tunnel oxide.

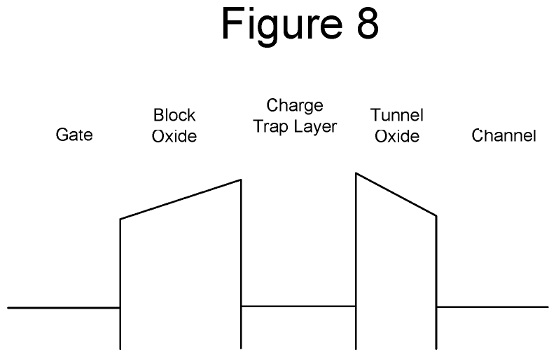

FIG. 8 depicts an example simplified band diagram of a memory cell that has undergone an embodiment of a shallow erase. After the shallow erase the block containing the memory cell may be placed into the shallow erase pool. Moreover, the block may remain in the shallow erase pool for an extended period of time prior to again programming the block. In an embodiment, the memory cell may be in a neutral state, which prevents charge pinning. The neutral state is represented in FIG. 8 by the absence of positive or negative charge in the charge trap layer. Note that the simplified band diagram is for one example memory cell that has undergone an embodiment of a shallow erase; however, not all memory cells that have undergone an embodiment of a shallow erase will have the same Vt. Therefore, the memory cells that have undergone an embodiment of a shallow erase may have a range of different Vts, as well as different amount of charge in the charge trap layer. For example, some memory cells that have undergone an embodiment of a shallow erase may have some positive charges in the charge trap layer, whereas other memory cells that have undergone an embodiment of a shallow erase may have some negative charges in the charge trap layer. When the memory system determines that the block should be programmed, the memory system may complete the erase process. This final erase may be performed quickly. Moreover, the initial shallow erase followed by the final erase may reduce damage to the memory cells that could occur if the memory cells were deeply erased from the programmed state. In one embodiment, the average (e.g., mean, median) Vt of a group of memory cells having undergone shallow erase will be non-negative. In contrast, after an embodiment of the final erase most of the memory cells may have a negative Vt.

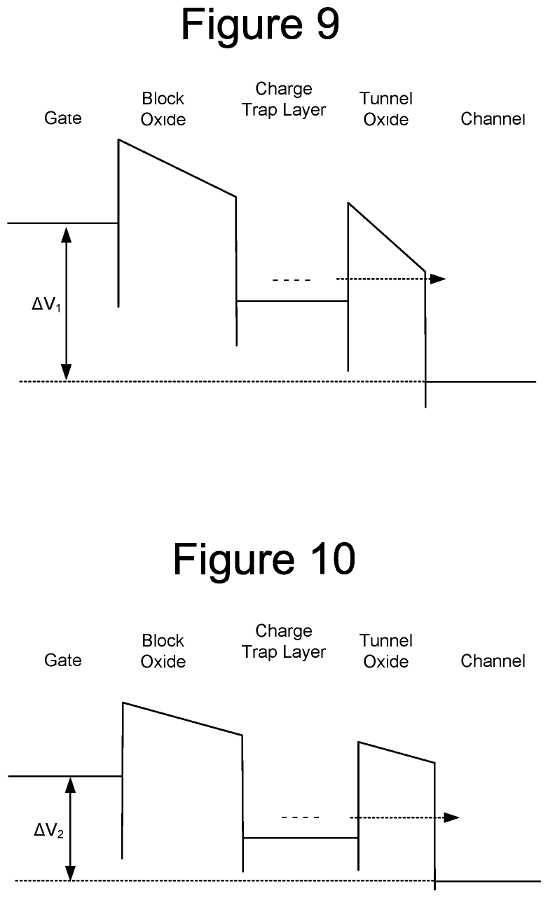

FIG. 9 shows another example simplified band diagram for a programmed memory cell undergoing an erase that uses a high erase voltage. The high erase voltage may be used conventionally to erase a block in the programmed state. This conventional erase process could potentially induce degradation to the tunnel oxide. The erase voltage needs to be high enough to dump all of the electrons from the charge trap layer to the channel. The voltage ΔV₁ represents the high erase voltage. This high erase voltage may create a very large transient voltage that could damage the tunnel oxide.

FIG. 10 shows an example simplified band diagram for a programmed memory cell undergoing an embodiment of a shallow erase that uses a significantly lower erase voltage than the example in FIG. 9. As an example, the erase voltage for an embodiment of a shallow erase may be about 5V lower than a typical erase voltage used to erase a programmed memory cell. The voltage ΔV₂ represents the smaller erase voltage. The smaller erase voltage may de-trap electrons from the charge trap layer in the shallow erase. The block is then placed in the shallow erase pool with memory cells having less charge in the charge trap layer than programmed memory cells in a programmed block. When the shallow erased block is pulled from the shallow erase pool for near term programming the erase process is completed. However, in this final erase process the tunnel oxide may see a smaller transient voltage, wherein damage to the tunnel oxide is prevented.

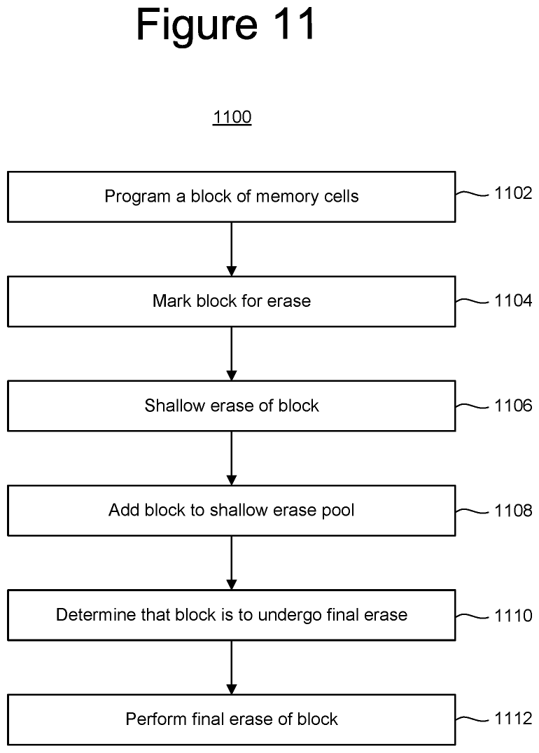

FIG. 11 is a flowchart of one embodiment of a process 1100 of shallow erase for erase pool management. The process 1100 may be performed by one or more control circuits. In an embodiment, the memory controller 120 instructs the system control logic 260 to perform the program and the erase. The system control logic 260 may control the program and erase at the die level. The memory controller 120 may manage the erase pool.

Step 1102 includes programming a block of memory cells. The memory cells could be programmed to any of number of bits per cell (e.g., 1 bit, 2 bits, 3 bits, 4 bits, etc.). At some point in time the memory system (e.g., memory controller 120) determines that the block is to be returned to the shallow erase pool and in step 1104 marks the block for erase.

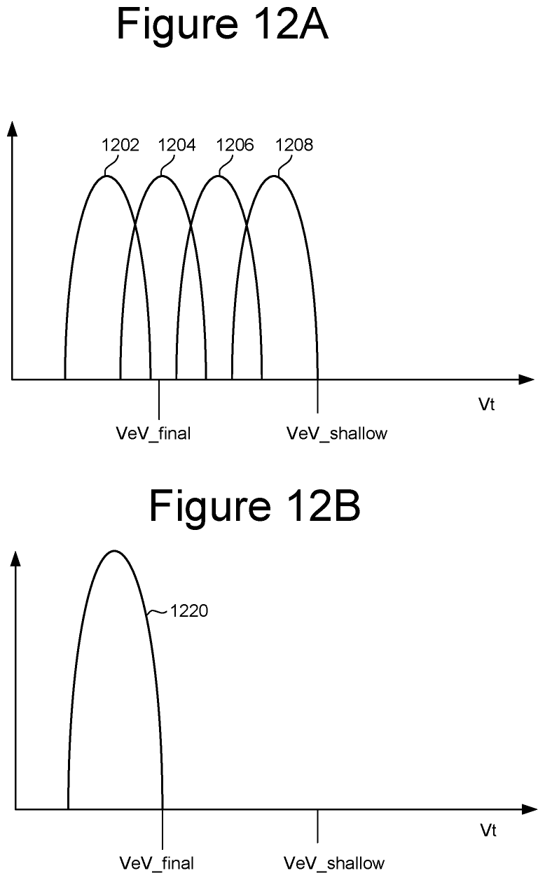

Step 1106 includes the memory system performing a shallow erase of the block. In an embodiment, after the shallow erase the block of memory cells are not yet at suitable levels for programming. For example, a significant number of memory cells may have a Vt that is higher than desired for successful programming. FIG. 12A shows example Vt distributions after one embodiment of a shallow erase in which the block was programmed to two bits per cell (four data states) in step 1102. Four Vt distributions 1202, 1204, 1206, 1208 are depicted. Prior to the shallow erase, Vt distribution 1202 was the erase state, Vt distribution 1204 was the A-state, distribution 1206 was the B-state, and distribution 1208 was the C-state. The shallow erase may have a very small impact on the erase Vt distribution 1202, and progressively greater impact for the higher Vt distributions. For example, the highest Vt distribution may be moved down the most. The highest Vt distribution 1208 has been moved down such that its upper tail is at a target voltage for the shallow erase (VeV_shallow). In an embodiment, the shallow erase compacts the threshold voltage distributions. In one embodiment, the shallow erase results in a non-negative average (e.g., mean, median) Vt of memory cells in the group.

An erase voltage that is used during the shallow erase may be referred to as a shallow erase voltage (or pulse). As will be discussed in further detail below, the shallow erase voltage may have a significantly lower magnitude than a nominal erase voltage used during the final erase. In one embodiment, a single erase voltage is applied in the shallow erase with no erase verify. Therefore, it is not required that the memory cells be verified with respect to VeV_shallow. However, in another embodiment, the memory cells are verified with respect to VeV_shallow in which case more than one shallow erase voltage can be applied.

Step 1108 includes adding the shallow-erased block to the shallow erase pool. Step 1108 may include the memory controller 120 adding an address of the block to a list in the shallow erase pool. Note that the memory system may perform a shallow erase of other blocks and add those blocks to the shallow erase pool prior to steps 1110 and 1112.

At some point in time the memory system (e.g., memory controller 120) determines that the block is to undergo a final erase (step 1110). The block can stay in the shallow erase pool for an extended period of time without significant risk of damage to, for example, the tunnel oxide. In one embodiment, the memory controller 120 determines that the block should undergo final erase responsive to a determination that there is or will soon be a need for a block for programming. For example, the block may be selected from the shallow erase pool responsive to a determination that the block is to be programmed within an allotted time (e.g., three days). In one embodiment, the memory controller 120 maintains a small pool of blocks that have undergone final erase and can determine that there is a need for more blocks in this final erase pool based on the number of blocks in the final erase pool, programming needs, etc.

Step 1112 includes performing a final erase of the block. FIG. 12B depicts an example Vt distribution 1220 for the memory cells after the final erase. In an embodiment, the memory system will verify the memory cells with respect to the final target erase level (VeV_final). Therefore, if needed more than one erase voltage may be applied to finalize the erase. In an embodiment, VeV_shallow is a positive voltage and VeV_final is a negative voltage. In one embodiment, the final erase results in a negative average (e.g., mean, median) Vt of memory cells in the group. In one embodiment, substantially all of the memory cells have a negative Vt after the final erase.

After the block has received its final erase, the block may be programmed. It is not required that the block be immediately programmed after the final erase, although that is one option. In an embodiment, the memory system 100 will program the block within an allotted time period after the final erase. For example, in an embodiment, the memory system 100 will program the final erased block within a few days. In an embodiment, the memory controller 120 could maintain a small pool of final erased blocks that are ready for programming.

FIG. 13 is a flowchart of one embodiment of a process 1300 of a shallow erase. In one embodiment, system control logic 260 controls the shallow erase at the die level. Process 1300 may be performed in one embodiment of step 1106 of FIG. 11. Step 1302 includes establishing the shallow erase voltage at a significantly lower voltage than a nominal erase voltage that may be used to erase memory cells below the final target erase level. In one embodiment, the shallow erase voltage is about 5V below a nominal erase voltage. However, the difference between the shallow erase voltage and the nominal erase voltage could be more than 5V or less than 5V. Step 1304 includes applying a single erase pulse to the memory cells. In an embodiment, the shallow erase pulse is applied to the channels of the memory cells with the control gates of the memory cells at about 0V. In some embodiments, the shallow erase pulse is applied to the bit lines and then transferred to the NAND channels. In some embodiments, the shallow erase pulse is applied to the source line(s) and then transferred to the NAND channels. In some embodiments, the shallow erase pulse is applied to both the bit lines and the source line(s) and then transferred to the NAND channels.

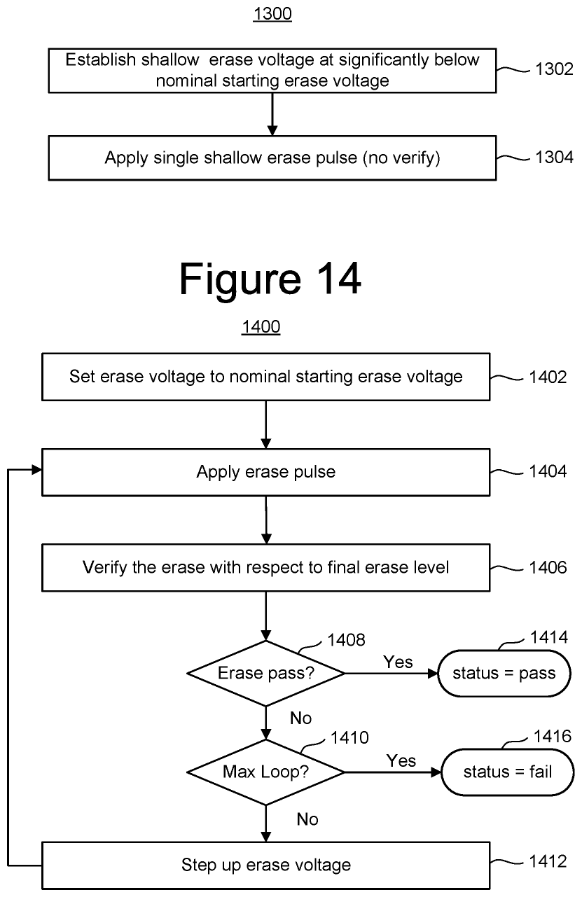

FIG. 14 is a flowchart of one embodiment of a process 1400 of a final erase. In one embodiment, system control logic 260 controls the final erase at the die level. Process 1400 may be performed in one embodiment of step 1112 of FIG. 11. Step 1402 includes establishing the erase voltage at a nominal erase voltage. In one embodiment, the nominal erase voltage is about 5V greater than the shallow erase voltage used in process 1300. The term “nominal erase voltage (or pulse)” as used herein refers to an erase voltage that is used in a process to erase memory cells to their final level. After being erased to their final levels the memory cells are suitable for programming. Note that all of the erase pulses in process 1400 may be referred to as nominal erase pulses.

Step 1404 includes applying an erase pulse to the memory cells. Step 1404 may be similar to step 1304 in FIG. 13. Step 1406 includes verifying the erase with respect to a final erase level (e.g., VeV_final in FIG. 12B). In one embodiment, the verification is performed on a NAND string basis where the memory system applies the erase verify voltage to all of the memory cell's control gates. The system may then determine how many NAND strings passed or failed the erase verify. The memory system may allow a few NAND strings to fail the erase test while still allowing for an overall pass of the erase process. If the memory system determines in step 1408 that the erase is not yet complete, then in step 1410 the memory system determines whether a maximum number of loops have been performed. If not, then in step 1412 the magnitude of the erase voltage may be stepped up. Then, the process returns to step 1404 to apply another erase pulse. After the erase passes the memory system returns a status of pass in step 1414. If the erase does not pass within an allotted number of loops then in step 1416 a status of fail is returned. Steps 1414 and 1416 may include the system control logic 260 returning the status to the memory controller 120.

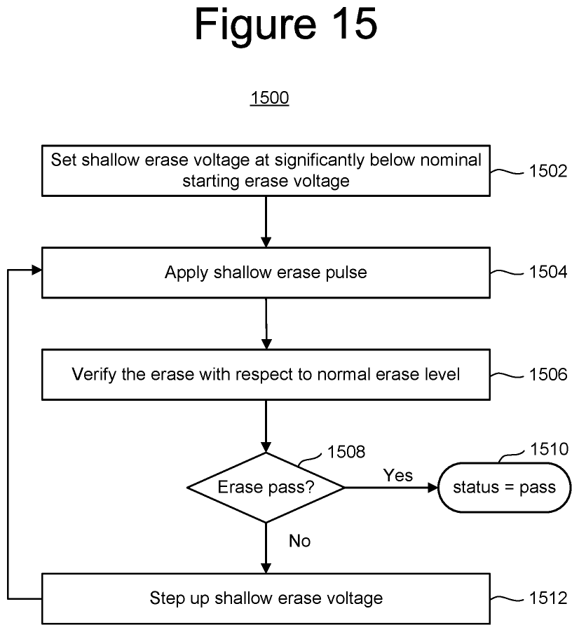

FIG. 15 is a flowchart of one embodiment of a process 1500 of a shallow erase. Process 1500 may be performed in one embodiment of step 1106 of FIG. 11. Step 1502 includes establishing the shallow erase at to a significantly lower voltage than the nominal erase voltage that may be used to erase memory cells below the final target erase level. In one embodiment, the erase voltage is about 5V below the nominal erase voltage. The difference between the shallow erase voltage and the nominal erase voltage used at the start of the final erase may be significantly greater than the erase voltage step size used in the final erase. Recall that the erase voltage may be stepped up in the final erase (see, for example, step 1412 in FIG. 14). As one example, the erase voltage may be stepped up about 1V in step 1412. However, in an embodiment, the difference between the shallow erase voltage and the nominal erase voltage is significantly greater than a typical step up.

Step 1504 includes applying a shallow erase pulse to the memory cells. Step 1504 may be similar to step 1304 in FIG. 13. Step 1506 includes verifying the erase with respect to a shallow erase level (e.g., VeV_shallow in FIG. 12A). In one embodiment, the verification is performed on a NAND string basis where the memory system applies the erase verify voltage to all of the memory cell's control gates. The system may then determine how many NAND strings passed or failed the erase verify. The memory system may allow a few NAND strings to fail the erase test while still allowing for an overall pass of the erase process. If the memory system determines in step 1508 that erase has passed then a status of pass is returned in step 1510. Step 1510 may include the system control logic 260 returning the status to the memory controller 120. If the memory system determines in step 1508 that erase has not yet passed then in step 1512 the magnitude of the erase voltage may be stepped up. Then, the process returns to step 1504 to apply another erase pulse. After the erase passes the memory system returns a status of pass in step 1510. The process 1500 may also add a test for a maximum number of loops. If the maximum number of loops is reached then the memory system may halt further erase at this time. However, the memory system does not necessarily return a status of erase fail, as erase may still be completed by the final erase process.

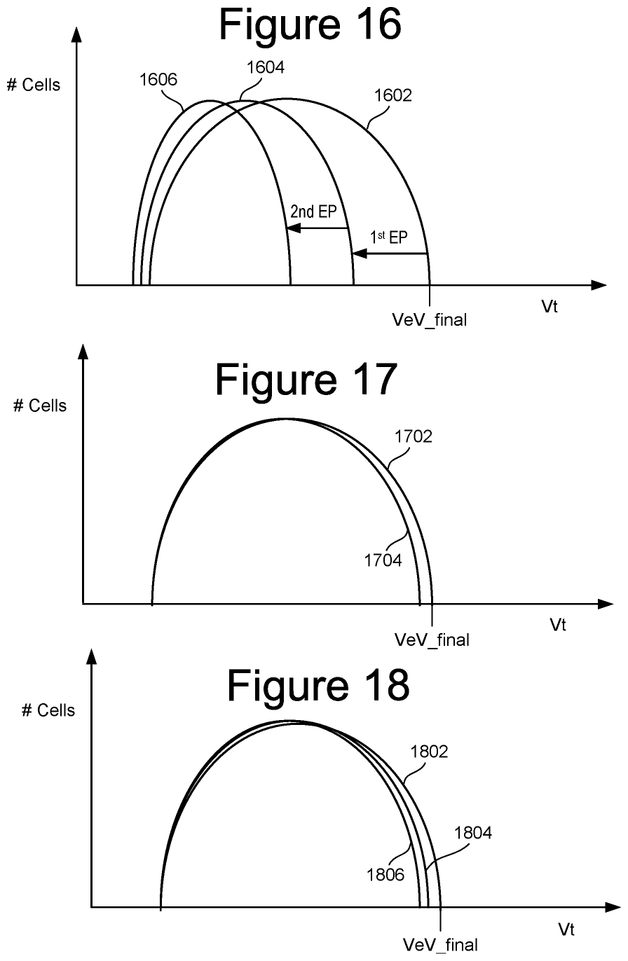

FIG. 16 depicts a change in an erase Vt distribution during a conventional erase process. The Vt distribution is for memory cells that started the erase already in the erase (Er) state. The diagram shows the initial Vt distribution 1602, the Vt distribution 1604 after one erase pulse and the Vt distribution 1606 after a second erase pulse. FIG. 16 shows that the memory cells end up an a fairly deeply erased (low Vt) state after the second erase pulse. In some cases, all of the memory cells in Vt distribution 1606 will have a negative Vt.

FIG. 17 depicts a change in an erase Vt distribution during an embodiment of a shallow erase. The Vt distribution is for memory cells that started the erase already in the erase state. The diagram shows the initial Vt distribution 1702 and the Vt distribution 1604 after one shallow erase pulse. FIG. 17 shows that the memory cells Vt are not nearly as deeply erased as in the conventional erase of FIG. 16. Therefore, the average (e.g., mean, median) Vt of memory cells in Vt distribution 1704 may be significantly greater than the average (e.g., mean, median) Vt of memory cells in Vt distribution 1606.

FIG. 18 depicts a change in an erase Vt distribution during an embodiment of a shallow erase. The Vt distribution is for memory cells that started the erase already in the erase state. The diagram shows the initial Vt distribution 1802, the Vt distribution 1804 after a first shallow erase pulse, and the Vt distribution 1806 after a second shallow erase pulse. FIG. 18 shows that the memory cells Vt are not nearly as deeply erased as in the conventional erase of FIG. 16. Therefore, the average (e.g., mean, median) Vt of memory cells in Vt distribution 1806 may be significantly greater than the average (e.g., mean, median) Vt of memory cells in Vt distribution 1606.

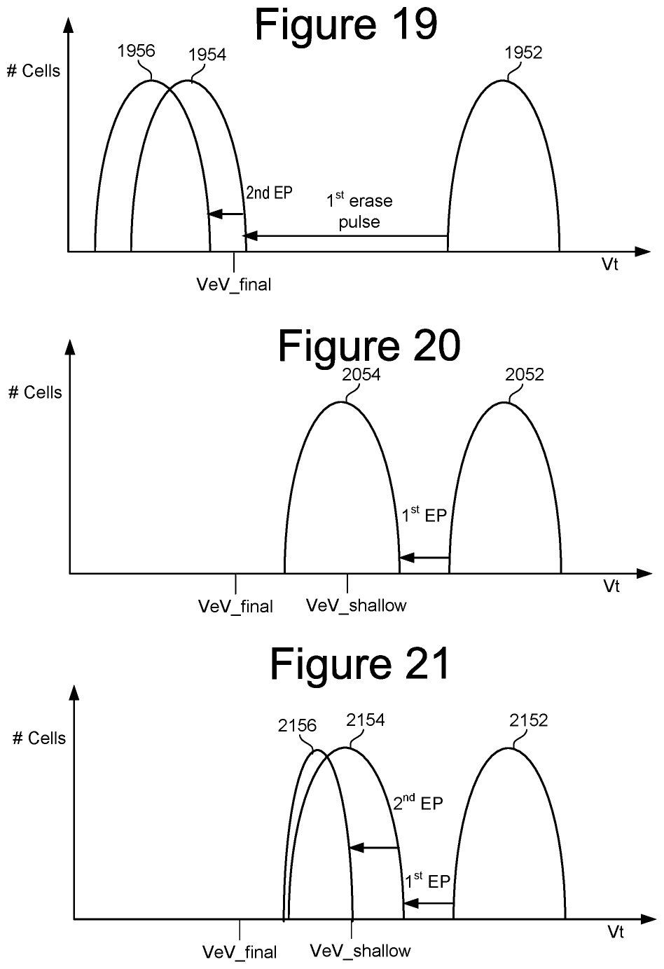

FIG. 19 depicts a change in a programmed Vt distribution during a conventional erase process. The programmed Vt distribution is for memory cells that were in a programmed data state prior to the conventional erase. More particularly, the programmed Vt distribution is for one of the higher Vt distributions. The diagram shows the initial programmed Vt distribution 1952, the Vt distribution 1954 after one conventional erase pulse and the Vt distribution 1956 after a second conventional erase pulse (2^{nd} EP). FIG. 19 shows that the first conventional erase pulse has a relatively high magnitude, which may result in the Vt distribution 1954 after one erase pulse being near or even below the final target erase voltage (VeV). Note that in some conventional techniques there is not an erase verify after the first erase pulse.

FIG. 20 depicts a change in a programmed Vt distribution during an embodiment of a shallow erase. The programmed Vt distribution is for memory cells that were in a programmed data state prior to shallow erase. More particularly, the programmed Vt distribution is for one of the higher Vt distributions. The diagram shows the initial programmed Vt distribution 2052 and the Vt distribution 2054 after one shallow erase pulse. FIG. 20 shows that the shallow erase pulse has a relatively low magnitude, which may result in the Vt distribution 2054 after one shallow erase pulse close to the shallow erase voltage (VeV_shallow). Note that the Vt distribution 2054 is an example and could be higher or lower than depicted after the first shallow erase pulse.

FIG. 21 depicts a change in a programmed Vt distribution during an embodiment of a shallow erase. The programmed Vt distribution is for memory cells that were in a programmed data state prior to shallow erase. More particularly the programmed Vt distribution is for one of the higher Vt distributions. The diagram shows the initial programmed Vt distribution 2152, the Vt distribution 2154 after a first shallow erase pulse, and a Vt distribution 2156 after a second shallow erase pulse. FIG. 21 shows that the shallow erase pulse has a relatively low magnitude, which may result in the Vt distribution 2154 after one shallow erase pulse close to the shallow erase voltage (VeV_shallow). If needed, one or more additional shallow erase pulses may be used to get the Vt distribution below the shallow erase voltage (VeV_shallow) as indicated by Vt distribution 2156.

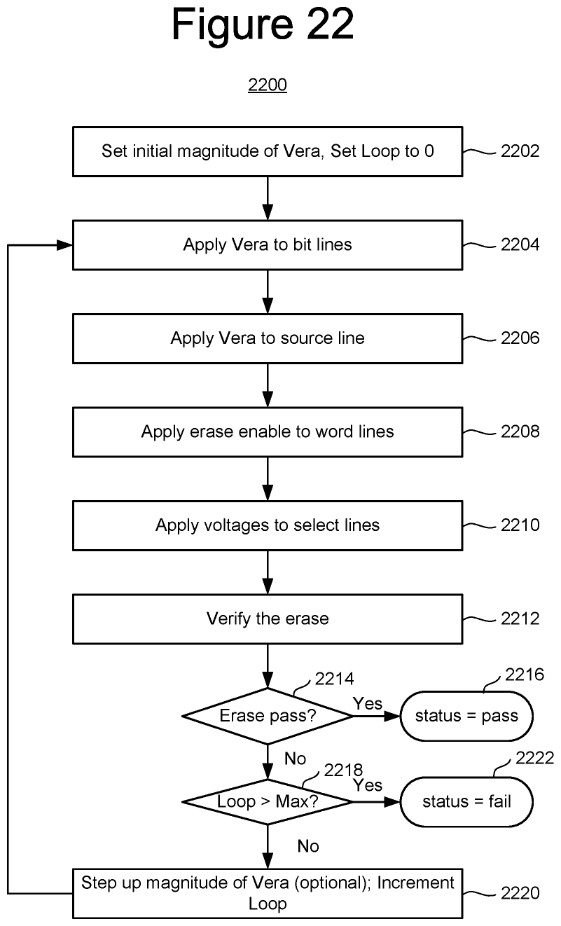

FIG. 22 is a flowchart describing one embodiment of a process 2200 for erasing memory cells. In an embodiment, circuitry on the die (200, 211) performs process 2200 in response to a command from memory controller 120. The process 2200 may be used to erase a group of NAND strings in a three-dimensional memory structure. The process 2200 may be used to perform an embodiment of a shallow erase. The process 2200 may be used to perform an embodiment of a final erase after a shallow-erased block has been accessed from the erase pool. Process 2200 describes a double sided erase in which an erase voltage (Vera) is applied at both ends of NAND strings (e.g., bit lines and source line). The erase in process 2200 is what is referred to herein as a gate induced drain leakage (GIDL) erase. A GIDL erase uses a GIDL current to charge up the NAND string channel. An erase enable voltage is applied to control gates of the memory cells, while maintaining the string channel potential to erase the memory cells. The GIDL current is generated by causing a drain-to-gate voltage at a select transistor (drain side and/or source side). The GIDL current may result when the select transistor drain voltage is significantly higher than the select transistor control gate voltage. GIDL current is a result of carrier generation, i.e., electron-hole pair generation due to band-to-band tunneling and/or trap-assisted generation. In one embodiment, GIDL current may result in one type of carriers, e.g., holes, predominantly moving into NAND channel 465, thereby raising the potential of the channel 465. The other type of carriers, e.g., electrons, are extracted from the channel 465, in the direction of a bit line or in the direction of a source line, by an electric field. During erase, the holes may tunnel from the channel to a charge storage region 463 of memory cells and recombine with electrons there, to lower the threshold voltage of the memory cells. Thus, in an embodiment of two-sided GIDL erase holes are provided from both the drain side and the source side.

Step 2202 includes setting an initial magnitude of an erase voltage (Vera). In an embodiment, the initial Vera may have a relatively low magnitude that is suitable for a shallow erase. As one example, the shallow erase Vera may be about 15V. In an embodiment, the initial Vera may have a relatively large magnitude suitable for a final eras. As one example, the final erase Vera may be about 20V. Step 2202 also includes setting a loop counter to 0. The loop counter will be used to track an allowed number of erase loops prior to ending process 2200 in the event erase has not yet passed. Step 2204 includes applying Vera to bit lines associated with the group of NAND strings being erased. Step 2206 includes applying Vera to one or more source lines associated with the group of NAND strings being erased.

Step 2208 includes applying an erase enable voltage to the word lines connected to the group of NAND strings being erased. In one embodiment, the erase enable voltage is 0V but could be other than 0V such as about 0.5V. Step 2210 includes applying a GIDL voltage to select lines (e.g., SGD, SGS). The GIDL voltage results in a GIDL current as described above. Also, the GIDL voltage allows Vera to pass to the NAND channels. Thus, the GIDL voltage (Vgidl) is a voltage that has a suitable magnitude to result in a GIDL current. In one embodiment, the GIDL voltage is about 12V less than Vera.

Thus, the erase of a memory cell includes applying an erase enable voltage (e.g., 0V) to the control gate of the memory cell while applying an erase voltage to a channel or body of the memory cell. An erase voltage is defined herein as a voltage applied to a channel or body of a memory cell that will erase the memory cell providing that the erase enable voltage is also applied to a control gate of that memory cell. A memory cell that has the erase voltage applied to its channel (body) may be inhibited from erase by applying an erase inhibit voltage to its control gate. An erase inhibit voltage is defined herein as a voltage that will inhibit erase of a memory cell despite the erase voltage being applied to a channel of that memory cell.

After steps 2204-2210 are performed, an erase verify may be performed in step 2212. For a shallow erase, the erase verify may be about VeV_shallow. For a final erase the erase verify may be about VeV_final. The erase verify voltage may be applied to each data WL connected to the group of NAND strings being erased. If all memory cells on a given NAND string have a Vt below the erase verify then the NAND string will conduct a significant current. Step 2214 is a determination of whether erase is complete. In an embodiment, the storage system 100 will count the number of NAND strings that have not yet passed erase. In an embodiment, if the number is below an allowed number, then the erase is allowed to pass. If erase has passed then the process 2200 completes with a status of pass in step 2216. If erase has not yet passed then a determination may be made in step 2218 of whether the loop counter has exceeded the maximum. In one embodiment, the erase process is allowed a certain number of loops to complete. If the loop count is greater than the maximum then the process ends with a status of fail in step 2222. If the loop count is not greater than the maximum then the process continues at step 2220. In step 2220, the magnitude of the erase voltage may optionally be increased. Also, the loop count is incremented. Then steps 2204-2218 are repeated.

Process 2200 may be modified by skipping certain steps to perform an embodiment of a shallow erase that does not verify. There is no need to set the loop count in step 2202, but the initial magnitude of Vera is set to a suitable value for a shallow erase. Steps 2204-2210 may be applied once. Then, the shallow erase process may end.

Whereas process 2200 in FIG. 22 is for a two-sided GIDL erase, one-sided GIDL erases are also possible. A drain-side GIDL erase is one example of a one-sided erase. In a drain-side GIDL erase Vera is applied to the bit lines but not to the source line. In a drain-side GIDL erase the GIDL current is only generated at the drain end of the NAND strings. Thus, in an embodiment of drain-side GIDL erase holes are provided from the drain side but not from the source side. A source-side GIDL erase is another example of a one-sided erase. In a source-side GIDL erase Vera is applied to the source line but not to the bit lines. In a source-side GIDL erase the GIDL current is only generated at the source end of the NAND strings. Thus, in an embodiment of source-side GIDL erase holes are provided from the source side but not from the drain side.

In view of the foregoing, a first embodiment includes an apparatus comprising one or more control circuits configured to connect to a memory structure having memory cells. The one or more control circuits are configured to perform a shallow erase of a group of the memory cells while the group of memory cells are in a plurality of data states. The one or more control circuits are configured to add the group of the memory cells to a shallow erase pool after the shallow erase. The one or more control circuits are configured to select the group of the memory cells from the shallow erase pool. The one or more control circuits are configured to perform a final erase of the group of the memory cells after selection from the shallow erase pool.

In a further embodiment, the one or more control circuits are configured to complete the shallow erase with a single erase voltage applied to the group of the memory cells without an erase verify.

In a further embodiment, the one or more control circuits are configured to perform the shallow erase of the group of the memory cells with a first erase verify that tests the group of the memory cells at a first reference voltage. The one or more control circuits are configured to perform the final erase of the group of the memory cells with a second erase verify that tests the group of the memory cells at a second reference voltage that is lower than the first reference voltage.

In a further embodiment, the first reference voltage is a positive voltage.

In a further embodiment, the second reference voltage is a negative voltage.

In a further embodiment, the one or more control circuits are further configured to apply a one or more shallow erase voltages to the group of the memory cells during the shallow erase, the one or more shallow erase voltages having a maximum shallow erase voltage having a largest magnitude of any of the one or more shallow erase voltages. The one or more control circuits are further configured to apply a one or more nominal erase voltages to the group of the memory cells during the final erase, including step up a magnitude of the nominal voltage during the final erase by a step size, wherein a minimum nominal erase voltage of the one or more nominal erase voltages is more than the step size greater than the maximum shallow erase voltage.

In a further embodiment, the one or more control circuits are further configured to erase the group of the memory cells to a non-negative median threshold voltage at a conclusion of the shallow erase. The one or more control circuits are further configured to erase the group of the memory cells to a negative median threshold voltage at a conclusion of the final erase.

In a further embodiment, the one or more control circuits are further configured to erase the group of the memory cells to a non-negative mean threshold voltage at a conclusion of the shallow erase. The one or more control circuits are further configured to erase the group of the memory cells such that substantially all of the memory cells in the group have negative threshold voltage at a conclusion of the final erase.

In a further embodiment, the memory cells are NAND memory cells, the plurality of data states are associated with a corresponding plurality of threshold voltage distributions, and the shallow erase compacts the plurality of threshold voltage distributions.

In a further embodiment, the one or more control circuits are configured to add additional shallow erased groups of memory cells to the shallow erase pool after adding the group of memory cells to the shallow erase pool. And the one or more control circuits are configured to select the group of the memory cells from the shallow erase pool after adding the additional shallow erased groups of memory cells to the shallow erase pool.

In a further embodiment, the one or more control circuits are configured to maintain a fully erased pool of groups of memory cells that have undergone the final erase after selection from the shallow erase pool. And the one or more control circuits are configured to program the groups of memory cells from the fully erased pool within a pre-determined time period.

In a further embodiment, the one or more control circuits are configured to select the group of the memory cells from the shallow erase pool responsive to identifying the group of memory cells in the shallow erase pool for near term programming. The term programming is to be performed within a pre-determined time period. And the one or more control circuits are configured to program the group of the memory within the pre-determined time period after the final erase.

An embodiment includes a method for managing an erase pool of NAND memory blocks. The method comprises programming a group of memory cells in a first block of NAND memory cells to a plurality of data states. The method comprises applying one or more shallow erase voltages to the first block of NAND memory cells while the group of memory cells are in the plurality of data states to shallow erase the first block. The method comprises adding the first block to a pool of shallow erased blocks after applying the one or more shallow erase voltages. The method comprises adding additional shallow erased blocks of NAND memory cells to the pool of shallow erased blocks after adding the first block to pool. The method comprises identifying the first block in the pool for near term programming after adding the additional shallow erased blocks to the pool. The method comprises applying one or more nominal erase voltages to the first block to fully erase the first block in response to identifying the first block for near term programming.

An embodiment comprises a non-volatile storage system. The system comprises a three-dimensional memory structure having NAND memory cells. The system comprises one or more control circuits configured to connect to the memory structure. The one or more control circuits are configured to program a block of NAND memory cells in the three-dimensional memory structure to programmed states. The one or more control circuits are configured to apply one or more shallow erase voltages to the block while the block is in the programmed states. The one or more control circuits are configured to add the block to a pool of shallow erased blocks after applying the one or more shallow erase voltages. The one or more control circuits are configured to select the block from the pool responsive to a determination that the block is to be programmed within an allotted time. The one or more control circuits are configured to apply one or more full erase voltages to the block after the block has been selected from the pool. The one or more control circuits are configured to program the block within the allotted time after applying the one or more full erase voltages.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus comprising:
one or more control circuits configured to connect to a memory structure having memory cells, wherein the one or more control circuits are configured to:
perform a shallow erase of a group of the memory cells while the group of memory cells are in a plurality of data states;
add the group of the memory cells to a shallow erase pool after the shallow erase;
select the group of the memory cells from the shallow erase pool; and
perform a final erase of the group of the memory cells after selection from the shallow erase pool.

2. The apparatus of claim 1, wherein the one or more control circuits are configured to:
complete the shallow erase with a single erase voltage applied to the group of the memory cells without an erase verify.

3. The apparatus of claim 1, wherein the one or more control circuits are configured to:
perform the shallow erase of the group of the memory cells with a first erase verify that tests the group of the memory cells at a first reference voltage; and
perform the final erase of the group of the memory cells with a second erase verify that tests the group of the memory cells at a second reference voltage that is lower than the first reference voltage.

4. The apparatus of claim 3, wherein the first reference voltage is a positive voltage.

5. The apparatus of claim 4, wherein the second reference voltage is a negative voltage.

6. The apparatus of claim 1, wherein the one or more control circuits are further configured to:
apply a one or more shallow erase voltages to the group of the memory cells during the shallow erase, the one or more shallow erase voltages having a maximum shallow erase voltage having a largest magnitude of any of the one or more shallow erase voltages; and
apply a one or more nominal erase voltages to the group of the memory cells during the final erase, including step up a magnitude of the nominal voltage during the final erase by a step size, wherein a minimum nominal erase voltage of the one or more nominal erase voltages is more than the step size greater than the maximum shallow erase voltage.

7. The apparatus of claim 1, wherein the one or more control circuits are further configured to:
erase the group of the memory cells to a non-negative median threshold voltage at a conclusion of the shallow erase; and
erase the group of the memory cells to a negative median threshold voltage at a conclusion of the final erase.

8. The apparatus of claim 1, wherein the one or more control circuits are further configured to:
erase the group of the memory cells to a non-negative mean threshold voltage at a conclusion of the shallow erase; and
erase the group of the memory cells such that substantially all of the memory cells in the group have negative threshold voltage at a conclusion of the final erase.

9. The apparatus of claim 1, wherein:
the memory cells are NAND memory cells;
the plurality of data states are associated with a corresponding plurality of threshold voltage distributions; and
the shallow erase compacts the plurality of threshold voltage distributions.

10. The apparatus of claim 1, wherein the one or more control circuits are configured to:
add additional shallow erased groups of memory cells to the shallow erase pool after adding the group of memory cells to the shallow erase pool; and
select the group of the memory cells from the shallow erase pool after adding the additional shallow erased groups of memory cells to the shallow erase pool.

11. The apparatus of claim 1, wherein the one or more control circuits are configured to:
maintain a fully erased pool of groups of memory cells that have undergone the final erase after selection from the shallow erase pool; and
program the groups of memory cells from the fully erased pool within a pre-determined time period.

12. The apparatus of claim 1, wherein the one or more control circuits are configured to:
select the group of the memory cells from the shallow erase pool responsive to identifying the group of memory cells in the shallow erase pool for near term programming, wherein near term programming is to be performed within a pre-determined time period; and
program the group of the memory within the pre-determined time period after the final erase.

13. A method for managing an erase pool of NAND memory blocks, the method comprising:
programming a group of memory cells in a first block of NAND memory cells to a plurality of data states;
applying one or more shallow erase voltages to the first block of NAND memory cells while the group of memory cells are in the plurality of data states to shallow erase the first block;
adding the first block to a pool of shallow erased blocks after applying the one or more shallow erase voltages;
adding additional shallow erased blocks of NAND memory cells to the pool of shallow erased blocks after adding the first block to pool;
identifying the first block in the pool for near term programming after adding the additional shallow erased blocks to the pool; and
applying one or more nominal erase voltages to the first block to fully erase the first block in response to identifying the first block for near term programming.

14. The method of claim 13, wherein identifying the first block in the pool for near term programming includes identifying the block for programming within a pre-determined time period.

15. The method of claim 13, wherein:
applying the one or more shallow erase voltages to the first block to shallow erase the first block includes erasing the memory cells in first block to a non-negative average threshold voltage; and
applying the one or more nominal erase voltages to the first block to fully erase the first block includes erasing substantially all of the memory cells in first block to a negative threshold voltage.

16. A non-volatile storage system, the system comprising:
a three-dimensional memory structure having NAND memory cells; and
one or more control circuits configured to connect to the memory structure, the one or more control circuits configured to:
program a block of NAND memory cells in the three-dimensional memory structure to programmed states;
apply one or more shallow erase voltages to the block while the block is in the programmed states;
add the block to a pool of shallow erased blocks after applying the one or more shallow erase voltages;
select the block from the pool responsive to a determination that the block is to be programmed within an allotted time;
apply one or more full erase voltages to the block after the block has been selected from the pool; and
program the block within the allotted time after applying the one or more full erase voltages.

17. The non-volatile storage system of claim 16, wherein the one or more control circuits are configured to:
erase the memory cells in the block to a non-negative average threshold voltage as a result of applying the one or more shallow erase voltages; and
erase substantially all of the memory cells in the block to a negative threshold voltage as a result of applying the one or more full erase voltages.

18. The non-volatile storage system of claim 16, wherein the one or more control circuits are configured to:
apply a single shallow erase voltage to the block of the memory cells while the block is in the programmed states.

19. The non-volatile storage system of claim 16, wherein the one or more control circuits are configured to:
verify whether the block of the memory cells pass a shallow erase verify as a result of applying the one or more shallow erase voltages, the shallow erase verify being a positive reference voltage; and
verify whether the block of the memory cells pass a final erase verify as a result of applying the one or more full erase voltages, the final erase verify being a negative reference voltage.

20. The non-volatile storage system of claim 16, wherein the one or more control circuits are configured to:
step up a magnitude of the full erase voltages by a step size between erase loops; and
increase a magnitude of a first of the full erase voltages relative to a last of the shallow erase voltages by more than the step size.
